(19) United States
(12) Patent Application Publication
(10) Pub. No.: US 2025/0132149 A1
(43) Pub. Date: Apr. 24, 2025

(54) HYDROGEN BARRIERS AND RELATED STRUCTURES, SYSTEMS, AND METHODS

(71) Applicant: ASM IP Holding B.V., Almere (NL)

(72) Inventors: Aditya Chauhan, Ottignies-Louvain-la-Neuve (BE); Vivek Koladi Mootheri, Leuven (BE); Lorenzo Bottiglieri, Helsinki (FI); Andrea IIIiberi, Leuven (BE); Michael Eugene Givens, Oud-Heverlee (BE)

(21) Appl. No.: 18/918,187

(22) Filed: Oct. 17, 2024

Related U.S. Application Data
(60) Provisional application No. 63/544,690, filed on Oct. 18, 2023.

(51) Int. Cl. H01L 21/02; C23C 16/44; C23C 16/455; H01L 29/786

(52) U.S. Cl. CPC H01L 21/0228; C23C 16/4408; C23C 16/45536; C23C 16/45553; H01L 21/02205; H10D 30/6755

(57) ABSTRACT

Methods for forming hydrogen barriers for, for example, channel layers in thin film transistors. The hydrogen barriers can comprise doped dielectrics such as magnesium-doped aluminum oxide. Further described are related structures and systems.

### CROSS-REFERENCE TO RELATED APPLICATION(S)

This Application claims the benefit of U.S. Provisional Application 63/544,690 filed on Oct. 18, 2023, the entire contents of which are incorporated herein by reference.

### FIELD OF INVENTION

The present disclosure is in the field of semiconductor device manufacture, in particular in the field of hydrogen diffusion barriers for hydrogen-sensitive semiconductors.

### BACKGROUND OF THE DISCLOSURE

Thin film transistors, such as those used in memory architectures such as DRAM, can employ semiconductors as channel materials. Some semiconductors such as Indium Gallium Zinc Oxide poorly withstand hydrogen. Nevertheless, many semiconductor processing techniques involve hydrogen, either as a process gas or as a by product. Thus, there is a need for ways to protect hydrogen-sensitive semiconductors from hydrogen.

### SUMMARY OF THE DISCLOSURE

Described herein is method that comprises providing a substrate to a reaction chamber and executing a cyclical deposition process to form a layer on the substrate, the cyclical deposition process comprising a plurality of cycles, ones from the plurality of cycles comprising a first metal precursor pulse, a second metal precursor pulse, and a reactant pulse, wherein the first metal precursor pulse comprises exposing the substrate to a first metal precursor comprising a metal halide; wherein the second metal precursor pulse comprises exposing the substrate to a second metal precursor, the second metal precursor comprising one or more of an alkaline metal and an alkaline earth metal; wherein the reactant pulse comprises exposing the substrate to one or more of an oxygen reactant, a nitrogen reactant, and a carbon reactant.

In some embodiments, the first metal precursor comprises a post transition metal.

In some embodiments, the post transition metal comprises aluminum.

In some embodiments, the first metal precursor comprises chlorine.

In some embodiments, the first metal precursor comprises aluminum trichloride.

In some embodiments, the second metal precursor comprises a metal-pi complex.

In some embodiments, the second metal precursor comprises one or more cyclopentadienyl ligands.

In some embodiments, the second metal precursor comprises magnesium.

In some embodiments, the second metal precursor comprises bis(cyclopentadienyl)magnesium.

In some embodiments, the reactant comprises an oxygen reactant, the oxygen reactant comprising oxygen.

In some embodiments, the oxygen reactant is selected from the list consisting of O₂, O₃, CO₂, N₂O, NO, and NO₂.

In some embodiments, subsequent pulses are separated by purges.

In some embodiments, at least one of the reactant pulse and one or more of the purges comprises generating a plasma and exposing the substrate to one or more active species.

Further described herein is a method of forming a structure. The method comprises providing a substrate to a reaction chamber; forming a hydrogen-sensitive semiconductor on the substrate; and, forming a hydrogen barrier on the substrate.

In some embodiments, forming the hydrogen barrier comprises carrying out a method as described herein.

In some embodiments, forming the hydrogen-sensitive semiconductor on the substrate comprises executing a cyclical semiconductor deposition process, the cyclical semiconductor deposition process comprising executing a plurality of semiconductor deposition cycles, ones from the plurality of deposition cycles comprising at least one semiconductor precursor pulse and at least one oxygen reactant pulse.

In some embodiments, the at least one semiconductor precursor pulse comprises an indium precursor pulse, a gallium precursor pulse, and a zinc precursor pulse.

In some embodiments, forming the hydrogen barrier is carried out after forming the hydrogen-sensitive semiconductor.

Further described herein is a structure comprising a substrate, a hydrogen-sensitive semiconductor overlying the substrate, and a hydrogen barrier overlying the hydrogen-sensitive semiconductor, wherein the hydrogen barrier protects the hydrogen-sensitive semiconductor from hydrogen.

Further described herein is a system comprising a reaction chamber, at least one precursor source, a reactant source, and a controller, wherein the system is constructed and arranged for executing a method as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 shows an embodiment of a method that can be employed to form a layer on a substrate.

FIG. 2 shows a flow chart of an embodiment of a method as described herein.

FIGS. 3 and 4 show embodiments of structures as described herein.

FIGS. 5 to 8 show embodiments of systems as described herein.

FIG. 9 shows an embodiment of a method as disclosed herein.

FIGS. 10 and 11 show experimental data regarding embodiments of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a cyclic deposition process as disclosed herein refers to an atomic layer deposition process.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). Indeed, purges can separate subsequent pulses by intermittently exposing the substrate to a purge gas. In some embodiments, each pulse is followed by a purge with a purge gas. Suitable purge gasses include inert or substantially inert gasses. In some embodiments, the purge gas comprises one or more of N₂ and a noble gas. Suitable noble gasses include He, Ne, Ar, Kr, and Xe.

Generally, for ALD processes, during each cycle, a precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber. Note that, as used herein, ALD processes are not necessarily comprised of a sequence of self-limiting surface reactions.

### Preliminary Remarks

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

### General Intro

Described herein are methods, systems, and structures which can be useful in the manufacture of semiconductor circuits such as memories, displays, etc.

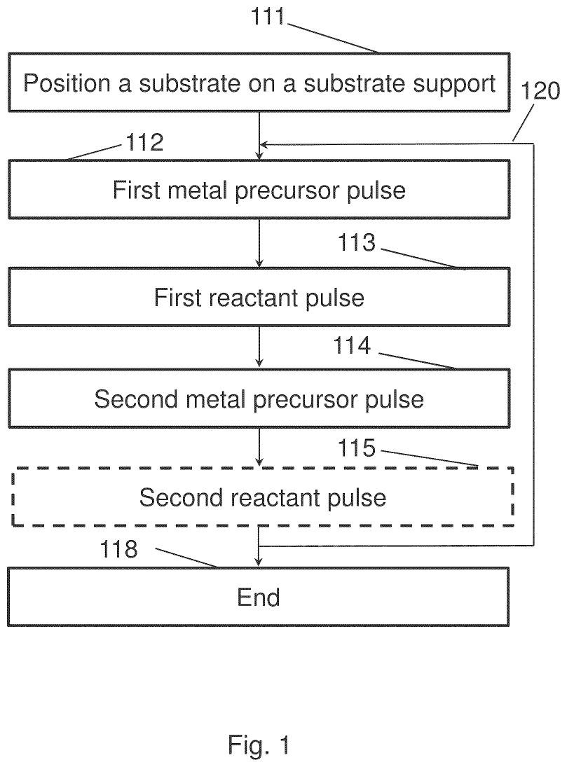

### Method—Embodiment FIG. 1

A particular embodiment of a method according to the present disclosure is described with respect to FIG. 1. FIG. 1 shows an embodiment of a method that can be employed to form a layer on a substrate. The method comprises a step 111 of providing a substrate to a reaction chamber, which can comprise positioning the substrate on a substrate support. Then, a cyclical deposition process can be executed to form a layer on the substrate. The cyclical deposition process comprising a plurality of cycles 120. Ones from the plurality of cycles comprise a first metal precursor pulse 112, a second metal precursor pulse 114, and a first reactant pulse 113. Optionally, ones from the plurality of cycles further comprise a second reactant pulse 115. The pulses 112-115 can be carried out in any order. In some embodiments, a precursor pulse 112,114 is immediately followed by a reactant pulse 113,115. In some embodiments, the first metal precursor pulse 112 is directly followed by the second metal precursor pulse 114, which in turn can be followed by the first reactant pulse. In some embodiments, the second metal precursor pulse 114 is directly followed by the first metal precursor pulse 112, which in turn can be followed by the first reactant pulse.

The first metal precursor pulse comprises exposing the substrate to a first metal precursor. In some embodiments, the first metal precursor comprises a metal halide. Suitable metal halides are described elsewhere herein.

The second metal precursor pulse comprises exposing the substrate to a second metal precursor. In some embodiments, the second metal precursor comprises one or more of an alkaline metal and an alkaline earth metal.

The reactant pulse comprises exposing the substrate to a reactant. In some embodiments, the reactant can include one or more of an oxygen reactant, a nitrogen reactant, and a carbon reactant.

In some embodiments, one or more pulses 112-115 can be followed by a purge.

The cycles 120 can be repeatedly carried out until a material having a desired thickness has been deposited. After a material having a desired thickness has been deposited, the method ends 118. Of course, one or more of the cycles 120 can optionally comprise further pulses such as one or more further precursor pulses and one or more further reactant pulses. Optionally the further precursor pulses and further reactant pulses can optionally be separated from adjacent pulses by a purge.

### First Metal Precursor Info

In some embodiments, the first metal precursor comprises a transition metal. Suitably, the transition metal can be selected from the list consisting of Sc, Ti, V, Cr, Mn, Fe, co, Ni, Cu, Zn, Y, Zr, Nb, Mo, Ru, Rh, Pd, Ag, Cd, Lu, Hf, Ta, W, Re, Os, Ir, Pt, Au, and Hg. It shall be noted that transition metal precursors as such are known in the art.

In some embodiments, the first metal precursor comprises a rare earth metal. Suitably, the rare earth metal can be selected from the list consisting of La, Ce, Pr, Nd, Pm, Sm, Eu, Gd, Tb, Dy, Ho, Er, Tm, and Yb. It shall be noted that rare earth metal precursors as such are known in the art.

In some embodiments, the first metal precursor comprises a post transition metal. Suitably, the post transition metal can be selected from the list consisting of Al, Ga, In, Tl, Sn, Pb, and Bi. It shall be noted that post transition metal precursors as such are known in the art.

In some embodiments, the post transition metal comprises aluminum (Al).

In some embodiments, the first metal precursor comprises a halogen such as chlorine, bromine, and iodine.

In some embodiments, the first metal precursor comprises chlorine.

In some embodiments, the first metal precursor comprises a post transition metal halide, such as a post transition metal chloride, such as aluminum trichloride.

In some embodiments, first metal precursor comprises an element that has a negative formation enthalpy for hydride formation and that has a +2 valence. For example, the first metal precursor can comprise one or more elements selected from magnesium (Mg), calcium (Ca), barium (Ba), strontium (Sr), and zirconium (Zr).

### Second Metal Precursor Info

In some embodiments, the second metal precursor comprises a metal-pi complex.

In some embodiments, the second metal precursor comprises a transition metal-pi complex comprising a transition metal and one or more ligands, the one or more ligands comprising one or more carbon-carbon double bonds. Suitably, the transition metal can be selected from the list consisting of Sc, Ti, V, Cr, Mn, Fe, co, Ni, Cu, Zn, Y, Zr, Nb, Mo, Ru, Rh, Pd, Ag, Cd, Lu, Hf, Ta, W, Re, Os, Ir, Pt, Au, and Hg. It shall be noted that transition metal precursors as such are known in the art.

In some embodiments, the second metal precursor comprises one or more cyclodienyl ligands, e.g. one or more cyclopentadienyl ligands.

In some embodiments, the second metal precursor comprises one or more alkylacetamidinato ligands.

In some embodiments, the second metal precursor comprises one or more alkylcyclopentadienyl ligands.

In some embodiments, the second metal precursor is selected from bis(N,N-di-sec-butylacetamidinato)-dimagnesium, [Mg(sBu₂AMD)]₂, and Bis(ethylcyclopentadienyl)magnesium, Mg(EtCp)₂.

In some embodiments, the second metal precursor comprises an alkaline earth metal such as Be, Mg, Ca, Sr, and Ba. In some embodiments, the second metal precursor comprises magnesium.

In some embodiments, the second metal precursor comprises bis(cyclopentadienyl)magnesium.

In some embodiments, second metal precursor comprises an element that has a negative formation enthalpy for hydride formation and that has a +2 valence. For example, the second metal precursor can comprise one or more elements selected from magnesium (Mg), calcium (Ca), barium (Ba), strontium (Sr), and zirconium (Zr).

### Reactant Info

In some embodiments, the reactant comprises an oxygen reactant. Suitably, the oxygen reactant comprises oxygen. In some embodiments, the oxygen reactant is selected from the list consisting of O₂, O₃, CO₂, N₂O, NO, and NO₂. In some embodiments, the oxygen reactant does not comprise hydrogen. In some embodiments, the oxygen reactant does not comprise H₂O. In some embodiments the oxygen reactant comprises at least one of O₂ and O₃.

In some embodiments, the reactant comprises a carbon reactant. Suitable carbon reactants include hydrocarbons such as olefines such as ethene and alkanes such as methane.

In some embodiments, the reactant comprises a nitrogen reactant. Suitable nitrogen reactants include ammonia, hydrazine, and hydrazine derivatives

### Purges

In some embodiments, subsequent pulses are separated by purges.

### Plasma

In some embodiments, at least one of the reactant pulse and one or more of the purges comprises generating a plasma and exposing the substrate to one or more active species. In some embodiments, active species selected from ions and radicals. The plasma can be generated in a direct plasma system, a remote plasma system, or in an indirect plasma system. Various plasmas can be suitable, including capacitive plasmas, inductively coupled plasmas, and microwave plasmas.

### Structure Forming

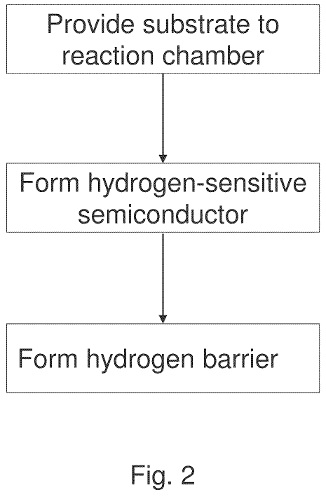

Further described herein is a method of forming a structure. With reference to FIG. 2, the method comprises providing a substrate to a reaction chamber; forming a hydrogen-sensitive semiconductor on the substrate; and, forming a hydrogen barrier on the substrate. In some embodiments, the hydrogen barrier is formed by means of a method as described herein.

### Semiconductor Deposition Methods

The hydrogen-sensitive semiconductor can be formed using any suitable deposition technique, including physical vapor deposition, chemical vapor deposition, and atomic layer deposition. In some embodiments, forming the hydrogen-sensitive semiconductor on the substrate comprises executing a cyclical semiconductor deposition process, the cyclical semiconductor deposition process comprising executing a plurality of semiconductor deposition cycles, ones from the plurality of deposition cycles comprising at least one semiconductor precursor pulse and at least one oxygen reactant pulse.

In some embodiments, the at least one semiconductor precursor pulse comprises an indium precursor pulse, a gallium precursor pulse, and a zinc precursor pulse. Thus, indium gallium zinc oxide (IGZO) can be formed. Hydrogen-sensitive semiconductors such as IGZO can degrade when exposed to hydrogen. The presently described hydrogen barriers can protect IGZO and other hydrogen-sensitive semiconductors from hydrogen.

### Barrier Forming Before or After Semiconductor

In some embodiments, forming the hydrogen barrier is carried out after forming the hydrogen-sensitive semiconductor. Additionally or alternatively, the hydrogen barrier can be formed before forming the hydrogen-sensitive semiconductor.

### EXAMPLE

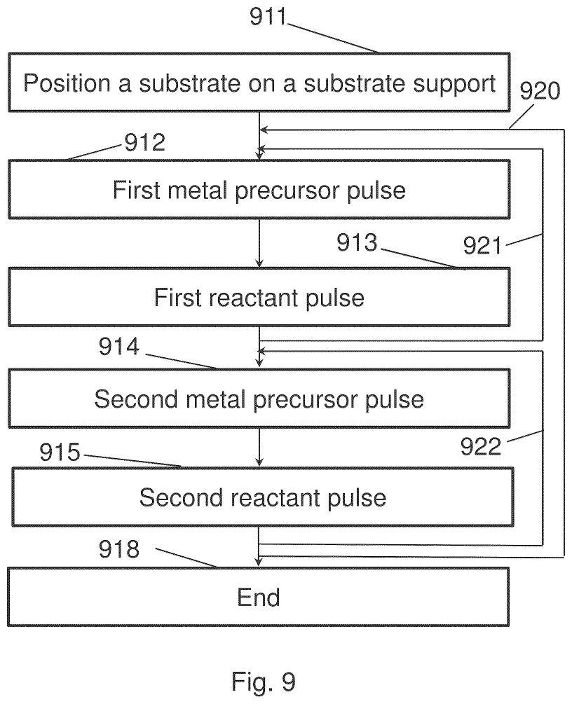

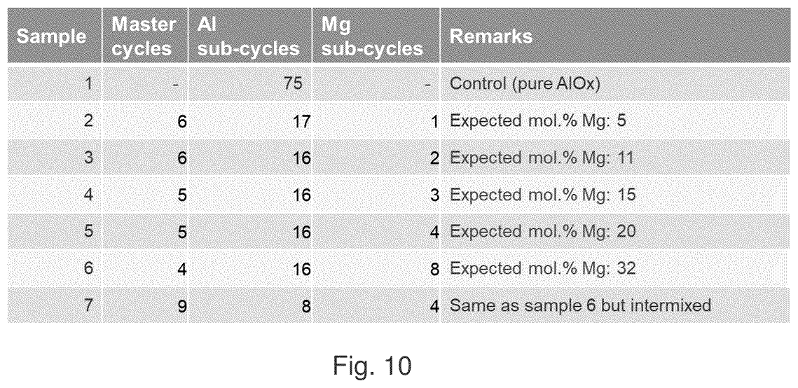

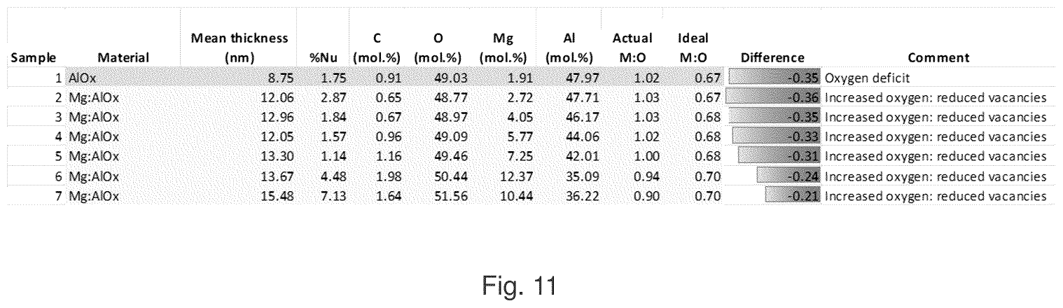

In a particular example, reference is to made to FIGS. 9 and 10

### Structure

Further described herein is a structure that comprises a substrate, a hydrogen-sensitive semiconductor overlying the substrate, and a hydrogen barrier overlying the hydrogen-sensitive semiconductor. The hydrogen barrier protects the hydrogen-sensitive semiconductor from hydrogen. In some embodiments, the hydrogen-sensitive semiconductor comprises indium, gallium, zinc, and oxygen.

### MIMCAP

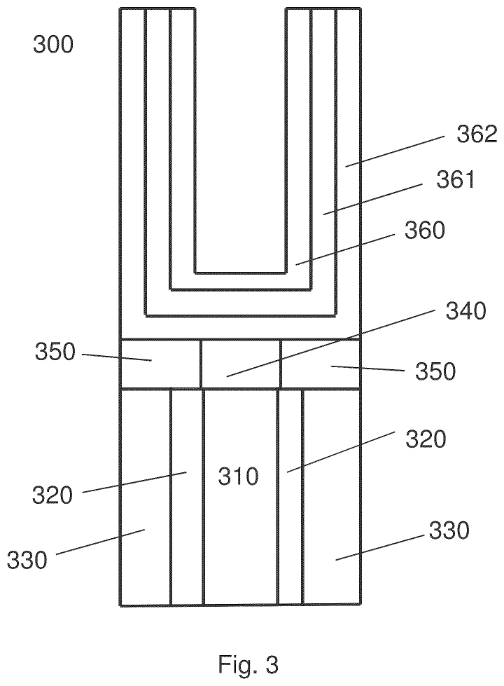

An exemplary structure 300 according to an embodiment of the present disclosure is described with reference to FIG. 3. The structure 300 of FIG. 3 can be employed as a capacitive memory element, e.g. in a DRAM memory. The structure comprises a channel material 310. Suitable channel materials include hydrogen-sensitive semiconductors, such as semiconducting oxides such as indium gallium zinc oxide (IGZO). A gate oxide 320 separates the channel material 310 from a gate contact 330. In some embodiments, the gate oxide 320 and the gate contact 330 circumscribe, i.e. are wrapped around, the channel material 310. The structure further comprises a capacitor that comprises a first electrode 360 and a second electrode 362 which are separated by a high-k dielectric 361. The second electrode 362 can be electrically connected to the channel material 310 by means of a conductive material 340 such as a silicide. Suitably, the gate contact 330 can be electrically insulated from the second electrode 362 by means of an electrically insulating spacer material 350. Suitably, the gate oxide 320 can comprise a hydrogen barrier as described herein.

### TFT

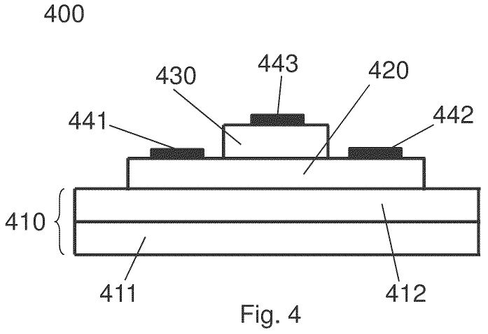

Another exemplary structure 400 according to an embodiment of the present disclosure is described with reference to FIG. 4. The structure 400 of FIG. 4 can be employed as a thin film transistor. The structure can comprise a substrate 410. The substrate can comprise a conductive layer 411 and an insulating layer 412. Suitable conductive layers 411 cam include low resistivity silicon, e.g. polysilicon, e.g. highly doped polysilicon. Suitable insulating layers can include silicon oxide. The structure 400 further comprises a channel material 420 overlying the insulating layer 412. Suitable channel materials 420 include hydrogen-sensitive semiconductors, such as semiconducting oxides such as indium gallium zinc oxide (IGZO). The structure further comprises a source contact 441 and a drain contact 442. The source contact 441 and the train contact 442 are in electrical contact with the channel material 420. Preferably the source and drain contacts 441,442 form ohmic contacts with the channel material 420. A gate dielectric 430 is disposed on the channel material 420 between the source and drain contacts 441,442. The gate dielectric 430 comprises a hydrogen barrier as described herein. A gate contact 443 overlies the gate dielectric 430.

### Barrier Composition

In some embodiments, the hydrogen barrier comprises a post transition metal, an alkaline earth metal, and oxygen. In some embodiments, the hydrogen barrier can comprise magnesium, aluminum, and oxygen. In some embodiments, the hydrogen barrier substantially comprises magnesium-doped aluminum oxide (Al₂O₃). For example, the hydrogen barrier can comprise magnesium-doped aluminum oxide that contains from at least 10¹⁹ to at most 10²² magnesium atoms per cubic centimeter, or from at least 10¹⁹ to at most 10²⁰ magnesium atoms per cubic centimeter, or from at least 10²⁰ to at most 10²¹ magnesium atoms per cubic centimeter, or from at least 10²¹ to at most 10²² magnesium atoms per cubic centimeter, or from at least 10²⁰ to at most 10²² magnesium atoms per cubic centimeter. In some embodiments, the hydrogen barrier comprises from at least 1 atomic percent magnesium to at most 50 atomic percent magnesium.

Advantageously, the magnesium doping in the aluminum oxide may block hydrogen diffusion through the magnesium-doped aluminum oxide.

In some embodiments, the hydrogen barrier comprises an element that has a negative formation enthalpy for hydride formation and that has a +2 valence. For example, the hydrogen barrier can comprise one or more elements selected from magnesium (Mg), calcium (Ca), barium (Ba), strontium (Sr), and zirconium (Zr).

In some embodiments, the hydrogen barrier comprises substantially no hydrogen. For example, the hydrogen concentration of hydrogen barrier can be less than 10⁹ hydrogen atoms per cubic centimeter, or less than 10⁷ hydrogen atoms per cubic centimeter, or substantially no hydrogen atoms per cubic centimeter.

Without the present disclosure being bound by any particular theory or mode of operation, it is believed that Mg2+ is an excellent dopant for Al₂O₃ hydrogen barriers at least because of the comparable size of Mg2+ and Al3+, and because of the high solid solubility of Mg2+ in Al₂O₃.

Without the present disclosure being bound by any particular theory or mode of operation, it is noted that oxygen vacancies are expected to be the primary route for diffusion of hydrogen in AlOx (via hopping mechanism). Mg has a high oxygen vacancy formation energy (Evo=9.8 eV) and a low reduction potential (E0=−2.38 V). Hence, with Mg-doping oxygen related defects can be easily suppressed even at lower anneal and deposition temperatures.

Advantageously, magnesium-doped aluminum oxide can be employed as a gate oxide for thin film transistors. Without the present disclosure being bound by any particular theory or mode of operation it is noted that MgO has a higher band gap (7.7 eV) compared to Al2O3 (7.0 eV). Hence, Mg-doping can increase the bandgap of the gate oxide thereby enabling lower thickness of the gate oxide.

Without the present disclosure being bound by any particular theory or mode of operation it is noted that doping of a divalent ion like Mg into a trivalent ion like Al creates defects. These defects act as stable trap sites for hydrogen. Atmospheric hydrogen thus, acts to compensate these defects and cannot diffuse further into the lattice.

### System

Further described herein is a system that comprises a reaction chamber, at least two precursor sources, a reactant source, and a controller. The system is constructed and arranged for executing a method as described herein.

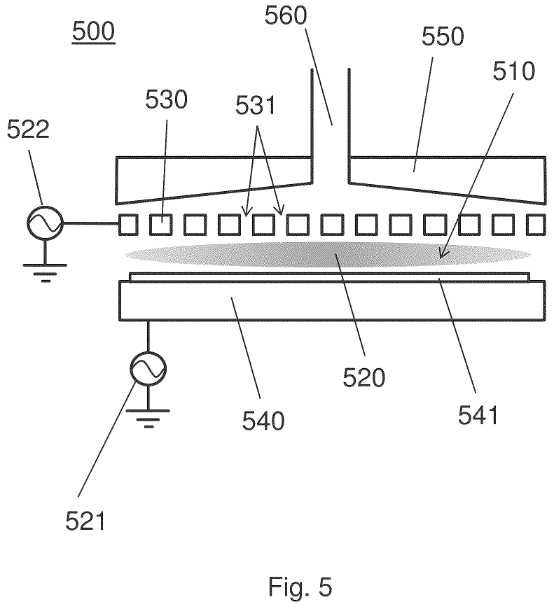

FIG. 5 shows a schematic representation of an embodiment of a system 500 as described herein. It can be used, for example, for forming a hydrogen barrier. The system 500 comprises a reaction chamber 510 in which a plasma 520 is generated. In particular, the plasma 520 is generated between a showerhead injector 530 and a substrate support 540. This is a direct plasma configuration employing a capacitively coupled plasma.

In the configuration shown, the system 500 comprises two alternating current (AC) power sources: a high frequency power source 521 and a low frequency power source 522. In the configuration shown, the high frequency power source 521 supplies radio frequency (RF) power to the showerhead injector, and the low frequency power source 522 supplies an alternating current signal to the substrate support 540. The radio frequency power can be provided, for example, at a frequency of 13.56 MHz or higher, e.g. at a frequency of at least 100 kHz to at most 50 MHz, or at a frequency of at least 50 MHz to at most 100 MHz, or at a frequency of at least 100 MHz to at most 200 MHz, or at a frequency of at least 200 MHz to at most 500 MHz, or at a frequency of at least 500 MHz to at most 1000 MHz, or at a frequency of at least 1000 MHz to at most 2000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz. Process gas comprising precursor, reactant, or both, is provided through a gas line 560 to a conical gas distributor 550. The process gas then passes through holes 531 in the showerhead injector 530 to the reaction chamber 510.

Whereas the high frequency power source 521 is shown as being electrically connected to the showerhead injector, and the low frequency power source 522 is shown as being electrically connected to the substrate support 540, other configurations are possible as well. For example, in some embodiments (not shown), both the high frequency power source and the low frequency power source can be electrically connected to the showerhead injector; or both the high frequency power source and the low frequency power source can be electrically connected to the substrate support; or the high frequency power source can be electrically connected to the substrate support, and the low frequency power source can be electrically connected to the showerhead injector.

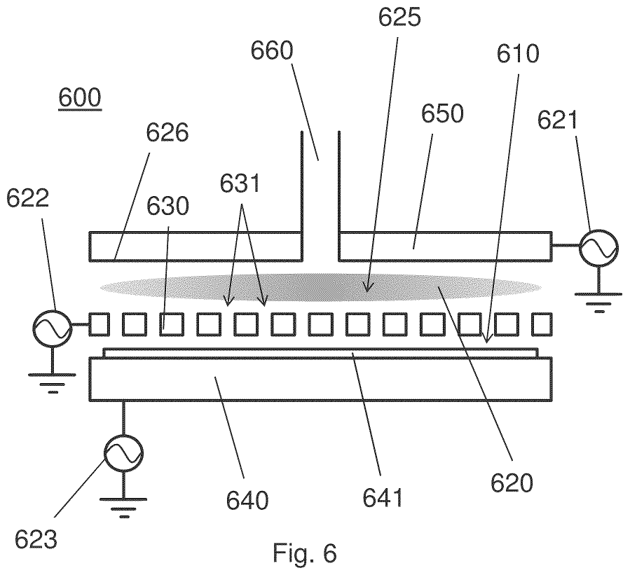

FIG. 6 shows a schematic representation of another embodiment of system 600 as described herein. It can be used, for example, for forming a hydrogen barrier. The configuration of the system of FIG. 6 can be described as an indirect plasma system. The system 600 comprises a reaction chamber 610 which is separated from a plasma generation space 625 in which a plasma 620 is generated. In particular, the reaction chamber 610 is separated from the plasma generation space 625 by a showerhead injector, and the plasma 620 is generated between the showerhead injector 630 and a plasma generation space ceiling 626.

In the configuration shown, the sub-system 600 comprises three alternating current (AC) power sources: a high frequency power source 621 and two low frequency power sources 622,623: a first low frequency power source 622 and a second low frequency power source 623. In the configuration shown, the high frequency power source 621 supplies radio frequency (RF) power to the plasma generation space ceiling, the first low frequency power source 622 supplies an alternating current signal to the showerhead injector 630, and the second low frequency power source 623 supplies an alternating current signal to the substrate support 640. A substrate 641 is provided on the substrate support 640. The radio frequency power can be provided, for example, at a frequency of 13.56 MHz or higher. The low frequency alternating current signal of the first and second low frequency power sources 622,623 can be provided, for example, at a frequency of 2 MHz or lower.

Process gas comprising precursor, reactant, or both, is provided through a gas line 660 that passes through the plasma generation space ceiling 626, to the plasma generation space 625. Active species such as ions and radicals generated by the plasma 625 from the process gas pass through holes 631 in the showerhead injector 630 to the reaction chamber 610.

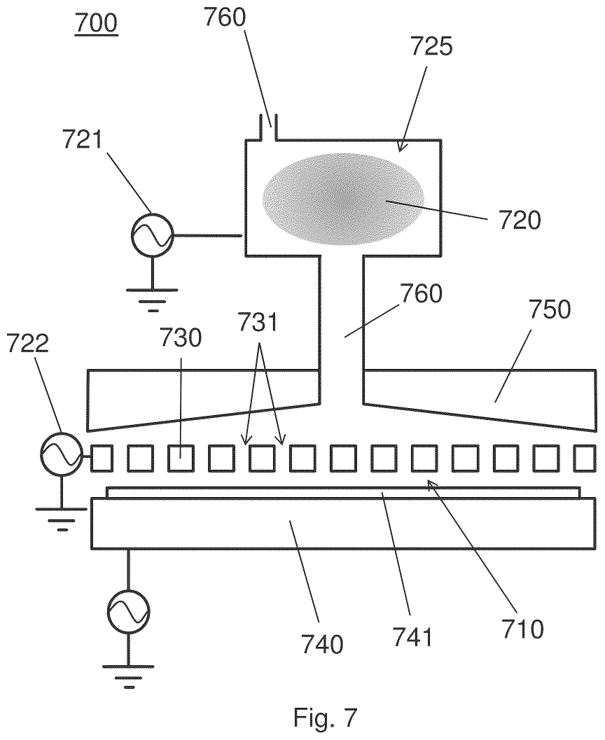

FIG. 7 shows a schematic representation of another embodiment of a system 700 as described herein. It can be used, for example, for forming a hydrogen barrier. The configuration of FIG. 7 can be described as a remote plasma system. The system 700 comprises a reaction chamber 710 which is operationally connected to a remote plasma source 725 in which a plasma 720 is generated. Any sort of plasma source can be used as a remote plasma source 725, for example an inductively coupled plasma, a capacitively coupled plasma, or a microwave plasma.

In particular, active species are provided from the plasma source 725 to the reaction chamber 710 via an active species duct 760, to a conical distributor 750, through holes 731 in a shower plate injector 730, to the reaction chamber 710. Thus, active species can be provided to the reaction chamber in a uniform way.

In the configuration shown, the system 700 comprises three alternating current (AC) power sources: a high frequency power source 721 and two low frequency power sources 722,723: a first low frequency power source 722 and a second low frequency power source 723. In the configuration shown, the high frequency power source 721 supplies radio frequency (RF) power to the plasma generation space ceiling, the first low frequency power source 722 supplies an alternating current signal to the showerhead injector 730, and the second low frequency power source 723 supplies an alternating current signal to the substrate support 740. A substrate 741 is provided on the substrate support 740. The radio frequency power can be provided, for example, at a frequency of 13.56 MHz or higher. The low frequency alternating current signal of the first and second low frequency power sources 722,723 can be provided, for example, at a frequency of 2 MHz or lower.

In some embodiments (not shown), an additional high frequency power source can be electrically connected to the substrate support. Thus, a direct plasma can be generated in the reaction chamber.

Process gas comprising precursor, reactant, or both, is provided to the plasma source 725 by means of a gas line 760. Active species such as ions and radicals generated by the plasma 725 from the process gas are guided to the reaction chamber 710.

### Thermal

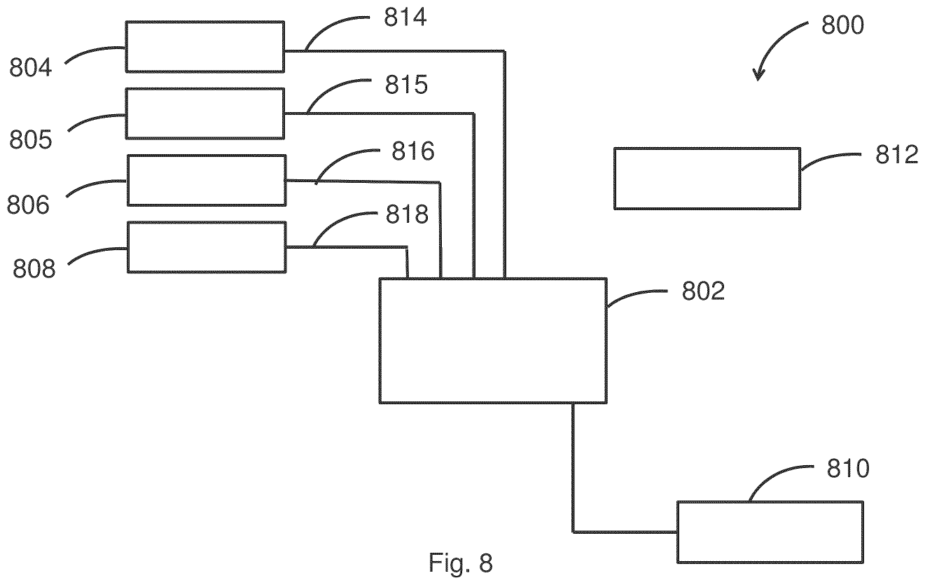

In some embodiments, the cyclical deposition process does not comprise generating a plasma or exposing the substrate to ions or radicals. In such embodiment, the cyclical deposition process can be described as being a thermal process. In such embodiments, the hydrogen barrier can be formed in an embodiment of a system 800 as described in FIG. 8. FIG. 8 illustrates a system 800 in accordance with exemplary embodiments of the disclosure. The system 800 can be used to perform a method as described herein and/or form a structure or device portion as described herein.

In the illustrated example, the system 800 includes one or more reaction chambers 802, a first precursor gas source 804, a reactant gas source 806, a purge gas source 808, an exhaust 810, and a controller 812.

The reaction chamber 802 can include any suitable reaction chamber, such as an ALD or CVD reaction chamber.

The first precursor gas source 804 can include a vessel and one or more precursors as described herein—alone or mixed with one or more carrier (e.g., noble) gases. The reactant gas source 806 can include a vessel and one or more reactants as described herein—alone or mixed with one or more carrier gases. The purge gas source 808 can include one or more noble gases as described herein. Although illustrated with four gas sources 804-808, the system 800 can include any suitable number of gas sources. The gas sources 804-808 can be coupled to reaction chamber 802 via lines 814-818, which can each include flow controllers, valves, heaters, and the like.

The exhaust 810 can include one or more vacuum pumps.

The controller 812 includes electronic circuitry and software to selectively operate valves, manifolds, heaters, pumps and other components included in the system 800. Such circuitry and components operate to introduce precursors and purge gases from the respective sources 804-808. The controller 812 can control timing of gas pulse sequences, temperature of the substrate and/or reaction chamber, pressure within the reaction chamber, and various other operations to provide proper operation of the system 800. The controller 812 can include control software to electrically or pneumatically control valves to control flow of precursors, reactants and purge gases into and out of the reaction chamber 802. The controller 812 can include modules such as a software or hardware component, e.g., a FPGA or ASIC, which performs certain tasks. A module can advantageously be configured to reside on the addressable storage medium of the control system and be configured to execute one or more processes.

Other configurations of the system 800 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 802. Further, as a schematic representation of a system, many components have been omitted for simplicity of illustration, and such components may include, for example, various valves, manifolds, purifiers, heaters, containers, vents, and/or bypasses.

During operation of the reactor system 800, substrates, such as semiconductor wafers (not illustrated), are transferred from, e.g., a substrate handling system to the reaction chamber 802. Once substrate(s) are transferred to the reaction chamber 802, one or more gases from the gas sources 804-808, such as precursors, reactants, carrier gases, and/or purge gases, are introduced into the reaction chamber 802.

1. A method that comprises providing a substrate to a reaction chamber and executing a cyclical deposition process to form a layer on the substrate, the cyclical deposition process comprising a plurality of cycles, ones from the plurality of cycles comprising a first metal precursor pulse, a second metal precursor pulse, and a reactant pulse,
wherein the first metal precursor pulse comprises exposing the substrate to a first metal precursor comprising a metal halide;
wherein the second metal precursor pulse comprises exposing the substrate to a second metal precursor, the second metal precursor comprising one or more of an alkaline metal and an alkaline earth metal; and
wherein the reactant pulse comprises exposing the substrate to one or more of an oxygen reactant, a nitrogen reactant, and a carbon reactant.

2. The method according to claim 1, wherein the first metal precursor comprises a post transition metal.

3. The method according to claim 2, wherein the post transition metal comprises aluminum.

4. The method according to claim 1, wherein the first metal precursor comprises chlorine.

5. The method according to claim 4, wherein the first metal precursor comprises aluminum trichloride.

6. The method according to claim 1, wherein the second metal precursor comprises a metal-pi complex.

7. The method according to claim 1, wherein the second metal precursor comprises one or more cyclopentadienyl ligands.

8. The method according to claim 1, wherein the second metal precursor comprises magnesium.

9. The method according to claim 1, wherein the second metal precursor comprises bis(cyclopentadienyl)magnesium.

10. The method according to claim 1, wherein the reactant pulse comprises an oxygen reactant, the oxygen reactant comprising oxygen.

11. The method according to claim 10, wherein the oxygen reactant is selected from a list consisting of O₂, O₃, CO₂, N₂O, NO, and NO₂.

12. The method according to claim 1, wherein subsequent pulses are separated by purges.

13. The method according to claim 12, wherein at least one of the reactant pulse and one or more of the purges comprises generating a plasma and exposing the substrate to one or more active species.

14. A method of forming a structure comprising,
providing a substrate to a reaction chamber;
forming a hydrogen-sensitive semiconductor on the substrate; and
forming a hydrogen barrier on the substrate.

15. The method according to claim 14, wherein forming the hydrogen-sensitive semiconductor on the substrate comprises executing a cyclical semiconductor deposition process, the cyclical semiconductor deposition process comprising executing a plurality of semiconductor deposition cycles, ones from the plurality of semiconductor deposition cycles comprising at least one semiconductor precursor pulse and at least one oxygen reactant pulse.

16. The method according to claim 15, wherein the at least one semiconductor precursor pulse comprises an indium precursor pulse, a gallium precursor pulse, and a zinc precursor pulse.

17. The method according to claim 14, wherein forming the hydrogen barrier is carried out after forming the hydrogen-sensitive semiconductor.

18. A structure comprising a substrate, a hydrogen-sensitive semiconductor overlying the substrate, and a hydrogen barrier overlying the hydrogen-sensitive semiconductor, wherein the hydrogen barrier protects the hydrogen-sensitive semiconductor from hydrogen.

19. A system comprising a reaction chamber, at least one precursor source, a reactant source, and a controller, wherein the system is constructed and arranged for executing a method according to claim 1.
